(19) United States
(12) Patent Application Publication
(10) Pub. No.: US 2007/0013042 A1
(43) Pub. Date: Jan. 18, 2007

(54) Electronic module assembly with heat spreader

(75) Inventors: Anna-Maria Henell, Helsinki (FI); Vesa T. Kyyhkynen, Helsinki (FI); Janne T. Nurminen, Oulunsalo (FI)

Correspondence Address: HARRINGTON & SMITH, LLP, 4 RESEARCH DRIVE, SHELTON, CT, 06484-6212, US

(73) Assignee: Nokia Corporation

(21) Appl. No.: 11/157,719

(22) Filed: Jun. 20, 2005

(51) Int. Cl. H01L 23/02

(52) U.S. Cl. 257/686

(57) ABSTRACT

An electronic module assembly including a first substrate; a first semiconductor die mounted to a top surface of the first substrate; a second substrate located above the first semiconductor die and electrically and mechanically connected to the top surface of the first substrate; a second semiconductor die mounted to a top surface of the second substrate; a heat spreader located above the second semiconductor die and thermally coupled to the second semiconductor die; and encapsulant material at least partially surrounding the second semiconductor die and the heat spreader.

### BACKGROUND OF THE INVENTION

1. Field of the Invention

The invention relates to an electronic module assembly and, more particularly, to an assembly with a heat spreader.

2. Brief Description of Prior Developments

In current electronic module components, thermal properties and behavior are becoming more and more critical as power dissipation levels increase and components become smaller and thinner. This results in high junction temperatures that may reduce the functionality of components and cause component break down. The risk for high component temperatures also sets limits for overall power dissipation levels in products.

A new type of electronic module assembly is being introduced having package-on-package components. For example, the electronic module assembly can comprise a first package having a Application Specific Integrated Circuit (ASIC) chip and a substrate, and a second package having a memory chip and a substrate. The second package is mounted on top of the first package, and the second package is electrically coupled to a printed circuit board through the substrate of the first package.

Some components, e.g. memory modules, have very low allowed maximum junction temperature. In the case of memories, this causes problems especially in package-on-package components, where the memory module is placed on top of some power dissipating ASIC. The lower component heats up the memory, and as it has also power dissipation of its own, the memory module junction temperature rises easily above critical limits; the junction temperature of the memory can be in normal use case situation of about 10-15° C. higher than allowed. With current technology used the maximum allowed temperature of the memories cannot be elevated, so some other solution to the problem must be found. Junction temperature rising above critical limit is also quite a common problem in other components, especially in those having localized heat sources on the die.

In the case of package-on-package components, the problem of too high temperature of memory is quite new, because the whole technology is novel. The problem is not currently solved. In other components the temperature of the die is lowered by adding copper to the component substrate for example. There are also components where the heat is directed upwards from the die with a heat slug (thermally conductive material between the die and the component top). The component top surface is then cooled with a heat sink.

There is a desire to provide a system and method for preventing excessively high temperatures in package-on-package component assemblies.

### SUMMARY OF THE INVENTION

In accordance with one aspect of the invention, an electronic module assembly is provided including a first substrate; a first semiconductor die mounted to a top surface of the first substrate; a second substrate located above the first semiconductor die and electrically and mechanically connected to the top surface of the first substrate; a second semiconductor die mounted to a top surface of the second substrate; a heat spreader located above the second semiconductor die and thermally coupled to the second semiconductor die; and encapsulant material at least partially surrounding the second semiconductor die and the heat spreader.

In accordance with another aspect of the invention, an electronic module assembly is provided comprising a first section comprising a first substrate and a first semiconductor die electrically and mechanically coupled to the first substrate; and a second section comprising a second substrate, a second semiconductor die electrically and mechanically coupled to the second substrate, a heat spreader mechanically and thermally coupled to the second semiconductor die and an encapsulant material at least partially surrounding the second semiconductor die and the heat spreader. The second substrate is electrically coupled to the first substrate by conductors extending directly between the substrates to form the electronic module assembly which is adapted to be mounted to an electronic member has a unitary assembly. The electronic module assembly is adapted to transfer heat from the second semiconductor die to the heat spreader, through the conductors, and through the first substrate to the electronic number.

In accordance with one method of the invention, a method of assembling an electronic module assembly is provided comprising providing a first subassembly comprising a first substrate and a first semiconductor die mounted to a top surface of the first substrate, wherein a bottom side of the first substrate is adapted to be operably mounted on an electronic member; providing a second subassembly comprising a second substrate, at least one second semiconductor die mounted to the second substrate above a top surface of the second substrate, and a heat spreader thermally coupled to the at least one second semiconductor die above a top surface of the second semiconductor die; and connecting the second substrate to the first substrate by conductors extending between a bottom side of the second substrate and the top surface of the first substrate. The heat spreader and conductors are adapted to transfer heat away from the second semiconductor die from the heat spreader to the conductors.

In accordance with another method of the invention, a method of transferring heat away from a semiconductor die in an electronic module assembly is provided comprising providing a heat spreader on top of the semiconductor die; transferring heat from the semiconductor die to the heat spreader; transferring heat from the heat spreader, through semiconductor die encapsulant material at least partially surrounding the heat spreader, to electrical conductors electrically connected to the semiconductor die; transferring heat from the electrical conductors to a first substrate of a first electronic module subassembly of the electronic module assembly; and transferring heat from the first electronic module subassembly to an electronic member which the first electronic module subassembly is mounted on.

### BRIEF DESCRIPTION OF THE DRAWINGS

The foregoing aspects and other features of the invention are explained in the following description, taken in connection with the accompanying drawings, wherein:

FIG. 1 is a perspective view of a mobile telephone incorporating features of the invention;

FIG. 2 is a schematic partial sectional view of a printed circuit board assembly in the phone shown in FIG. 1;

FIG. 3 is a schematic diagram showing a partial enlarged view of the components shown in FIG. 2;

FIG. 4 is. a top plan view of the lower package of the assembly shown in FIG. 3;

FIG. 5 is a cross-sectional and broken away top view of the second package of the assembly shown in FIG. 3;

FIG. 6 is a schematic diagram similar to FIG. 3 showing an alternate embodiment of the invention;

FIG. 7 is a schematic diagram showing an alternate embodiment of a package-on-package assembly comprising the invention; and

FIG. 8 is a schematic diagram illustrating location of components in another alternate embodiment of the invention.

### DETAILED DESCRIPTION OF THE PREFERRED EMBODIMENTS

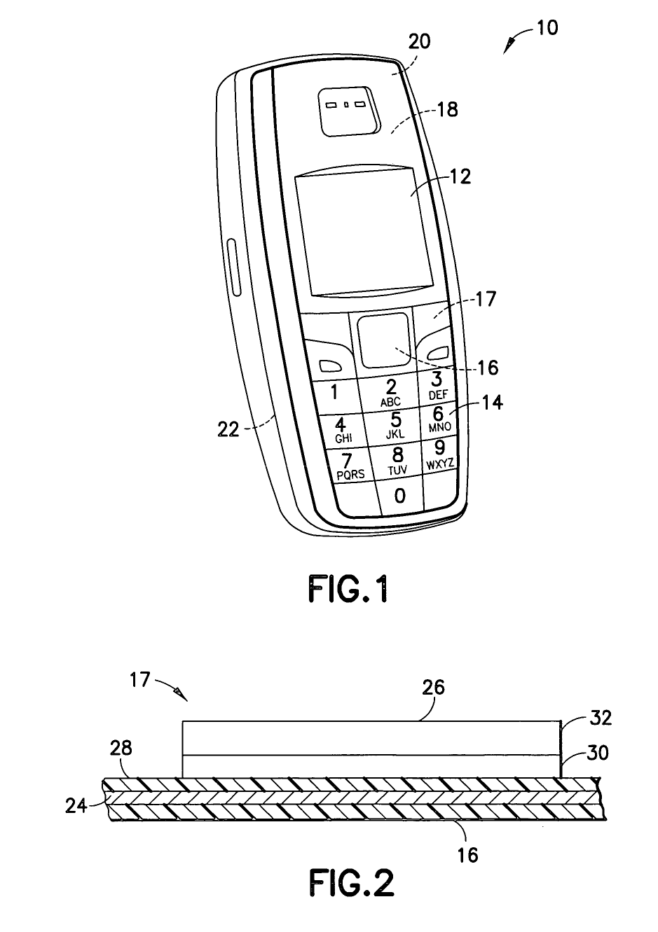

Referring to FIG. 1, there is shown a perspective view of a portable electronic device 10 incorporating features of the invention. Although the invention will be described with reference to the exemplary embodiments shown in the drawings, it should be understood that the invention can be embodied in many alternate forms of embodiments. In addition, any suitable size, shape or type of elements or materials could be used.

The device 10 comprises a hand-held communications device and, more specifically, a mobile telephone. However, features of the invention could be used in any suitable type of electronic device such as a PDA, laptop computer, gaming device, etc. The telephone 10 generally comprises a display 12, a keypad 14, a printed circuit board 16 having suitable electronic circuitry 17 including a transceiver 18, an antenna 20 and a battery 22. Additional or alternative features could be provided.

Referring also to FIG. 2, the printed circuit board 16 preferably comprises a ground layer 24 of electrically conductive material, such as metal, which can also function as a heat transfer for transferring heat away from the electronic circuitry. In this embodiment the electronic circuitry 17 comprises an electronic module assembly 26 which comprises a package-on-package assembly. The electronic module assembly 26 is mounted to a top side 28 of the printed wiring board or printed circuit board (PCB) 16 and electrically coupled to conductors of the printed circuit board. The assembly 26 could be attached to a bottom side of the printed circuit board. As used herein “top” and “bottom” are used merely as terms of reference to relate components relative to other components for an understanding of the invention, and should not be considered as limiting. The assembly 26 in this embodiment comprises two sections or packages 30, 32 in a stacked configuration. However, in alternate embodiments, more than two sections or packages could be provided.

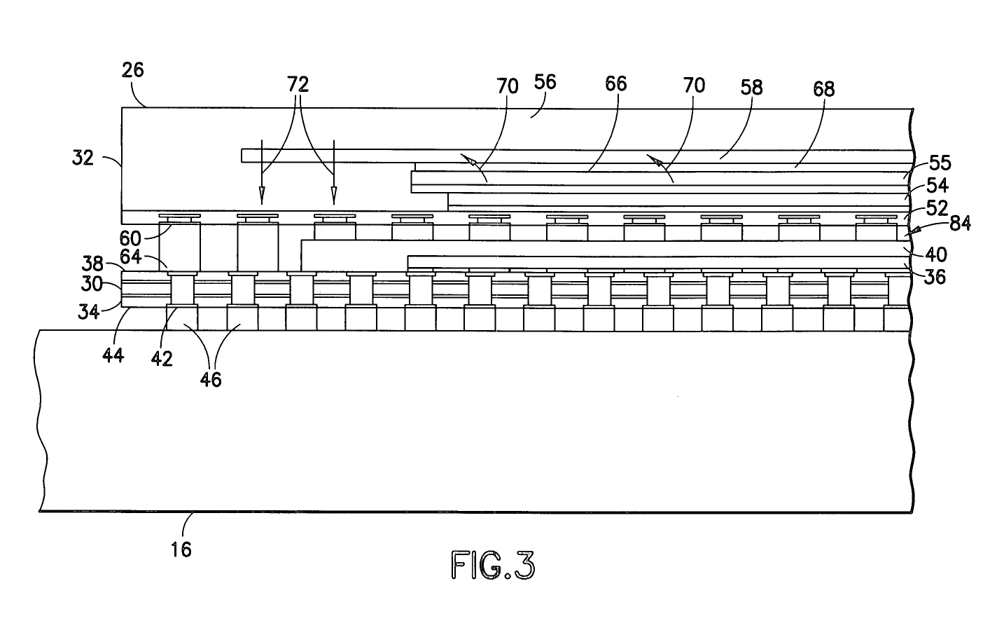

Referring also to FIG. 3, the first section 30 generally comprises a first substrate 34, a first semiconductor die 36 mounted to a top surface 38 of the first substrate 34, and a first encapsulant material 40 which substantially surrounds the first die 36. The first semiconductor die 36 could be any suitable type of semiconductor die such as a Application Specific Integrated Circuit (ASIC) chip for example, or any other type of power dissipating chip/assembly, or memory chip(s) for example. In an alternate embodiment the first section 30 could comprise more than one semiconductor die. Two or more of the dies could also be stacked on each other. The first substrate 34 has bottom contact areas 42 on a bottom side 44 of the substrate 34 which are electrically and mechanically coupled to the printed circuit board 16 by fusible elements 46, such as solder balls. In an alternate embodiment contacts could extend from the first substrate 34 to couple the first section 30 to the printed circuit board 16 rather than fusible elements.

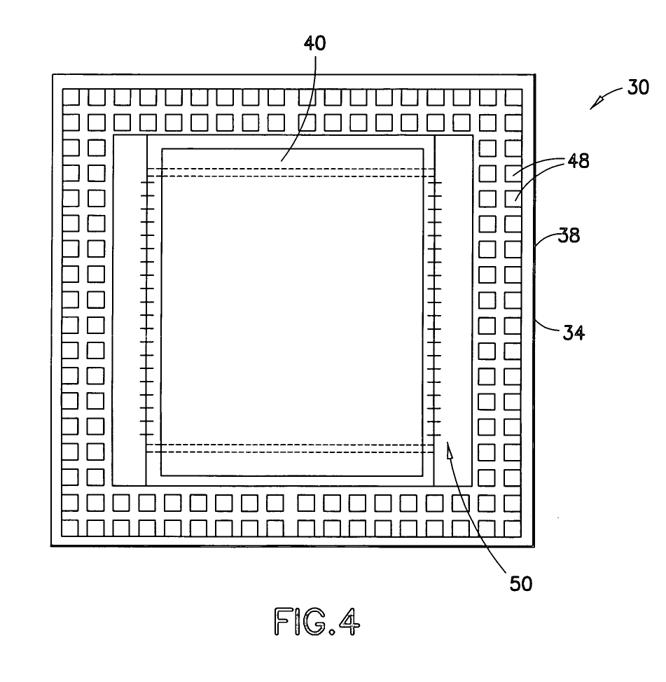

Referring also to FIG. 4, the top side 38 of the first substrate 34 comprises top contact areas 48. In this embodiment the top contact areas 48 are arranged around the perimeter of the first substrate in a general ring shape. However, any suitable configuration could be provided. As described further below, the contact areas 48 are provided to allow connection of the second section or package 32 to the printed circuit board 16 by means of the first substrate 34. In this embodiment, wire bonds 50 are provided to electrically connect the first semiconductor die 36 to the first substrate 34. However, any suitable electrical connection could be provided. The encapsulant material could also cover the wire bonds.

Referring back to FIG. 3, the second section or package 32 generally comprises a second substrate 52, two second semiconductor dies 54, 55, a second encapsulant material 56, and a heat spreader 58. In an alternate embodiment more or less than two second semiconductor dies could be provided. An air gap 84 can be provided between the top of the first encapsulant material 40 and the bottom of the second substrate 52. The air gap might be as small as about 0.1 mm for example.

The second semiconductor dies 54, 55 could be any suitable type of semiconductor die such as memory chips for example. In this embodiment the two dies 54, 55 are stacked one on top of the other. The second substrate 52 has bottom contact areas 60 on a bottom side 62 of the substrate 52 which are electrically and mechanically coupled to the contact areas 48 of the first substrate 34 by fusible elements 64, such as solder balls. In an alternate embodiment contacts could extend from the second substrate 52 to couple to the first substrate 34 rather than fusible elements. The second semiconductor dies 54, 55 are electrically coupled to the printed circuit board 16 by the fusible elements 46, 64 and the two substrates 34, 52. This type of package-on-package configuration takes up less of a footprint on the printed circuit board 16 and, thus, allows the size of the device 10 to be reduced.

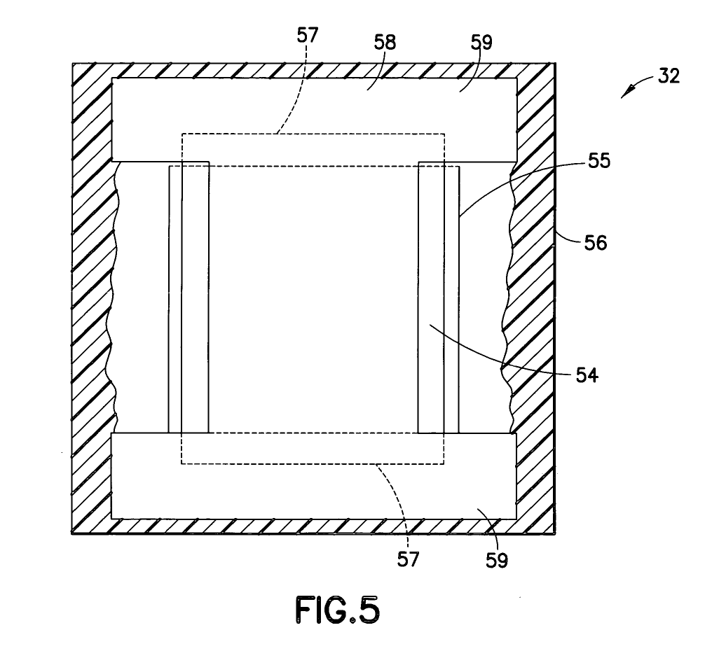

The heat spreader 58 comprises a heat transfer member and can be comprised of any suitable material or combination of materials such as aluminum, copper, silicon, etc. Referring also to FIG. 5, in this embodiment the heat spreader 58 comprises a flat general “I” shape. However, in alternate embodiments any suitable shape could be provided, such as square or rectangular for example. The heat spreader 58 is attached to the top side 66 of the top second die 55 by a thermally conductive attachment layer 68. The layer 68 could comprise thermally conductive adhesive, tape or glue for example. In alternate embodiments, any suitable type of connection of the heat spreader 58 to the die 55 could be provided so long as a thermal path is established for conducting heat from the die 55 to the heat spreader 58. In an alternate embodiment the heat spreader 58 could comprise multiple members. Additionally, or alternatively, the heat spreader(s) could be attached to the lower die 54, such as if both dies have their own heat spreader for example.

In the embodiment shown the heat spreader 58 is completely surrounded by the second encapsulant material 56 except at its connection to the top die 55. The heat spreader 58 could comprise holes which the encapsulant material is molded into to attach the two members together. If the heat spreader 58 is connected to ground, the spreader 58 could also function as an EMI shield. In an alternate embodiment a portion of the heat spreader could be exposed out of the second encapsulant material 56 for transferring heat to ambient air or to a heat sink (not shown).

As seen with arrows 70 in FIG. 3, heat from the top die 55 can be transferred to the heat spreader 58. The heat spreader 58 can transfer the heat towards the fusible elements 64 through the encapsulant material 56 as indicated by arrows 72. This allows the heat to be transferred through the first substrate 34 and fusible elements 46 to the PCB 16 and away from the dies of the assembly. This lowers the temperature of the dies 54, 55.

The invention comprises putting a heat spreader on top of at least one of the dies inside the component 26 similar to the way the dies are stacked on top of each other in die stack. The heat spreader can be totally insider the package, or could extend partially out of the package or be exposed at an edge for example. At least one portion of the heat spreader extends past the outer perimeter edge of the die which the heat spreader is attached to. In FIG. 5 the heat spreader has two skirt portions 59 which extend past two opposite ends 59 of the die 55.

The heat spreader may be of any material having adequate thermal conductivity value. The spreader is attached with thermally conductive glue/other adhesive to the die surface, and it can be of any shape as long as the area of it is preferably as large as possible. It can also be shaped so that it is bent on the outer edges to conduct the heat more efficiently towards the component substrate/solder balls. The heat spreader lowers the temperature of the die(s) by spreading the heat to a wider area, and directing the heat to be conducted by the component substrate/solder balls downwards to the PCB 16. It also can equalize the temperatures on the die in case of possible local hot spots and decreases the peak temperature values.

The heat spreader approach is beneficial especially in memory modules in package-on-package components, where a memory die having a low maximum allowed temperature is placed on top of a heat generating component, such as a processor component for example. In one embodiment, the heat spreader is put on top of the top die inside the memory component, in this embodiment section 32, where it effectively lowers its junction temperature, such as the pn junctions on top of the semiconductor die for example. In one use example the temperature of the die can be lowered from 100° C. to 94° C. For an ASIC package using 0.97 W of power and a memory package using 0.23 W of power (total of about 1.2 W), the use of the heat spreader can lower the junction temperature of the memory dies by about 5 degrees Celsius. This could lower the junction temperature below a critical limit of about 85° C. for example. It also is beneficial in components having localized hot spots on the die, such as EM ASICs for example. The heat spreader could also be used in a stand alone component (rather than in a package-on-package assembly) having localized hot spots on the die.

The heat spreader in the component lowers the temperatures allowing higher heat dissipation. It does not require thicker or otherwise larger component because the heat spreader could be of quite small thickness, such as only about 0.1 mm for example, and fits easily inside the component. From a component manufacturing point of view, the technology is quite easy to implement, at least with a flat shaped heat spreader, by merely using the same attachment technology as used when stacking the dies. The thermal spreader can be shaped so that it allows bonding of the top die 55 from the edges; as is also the case when dies are stacked on top of each other. The spreader can be shaped so that the die(s) 54, 55 underneath the spreader can be wire bonded from the sides.

The heat spreader could be used in any suitable type of package-on-package component, such as in memory components in phone products for example or in other components having risk for a junction temperature which would otherwise be too high. In the past, thermal problems with memory dies have not been a problem. However, a new problem has been created with memory dies when packaged into the new form of package-on-package assemblies. Only now, when package-on-package modules have started to be taken into use, has this problem arisen. The invention overcomes this over-temperature problem of a memory die in a package-on-package assembly that was previously unaddressed.

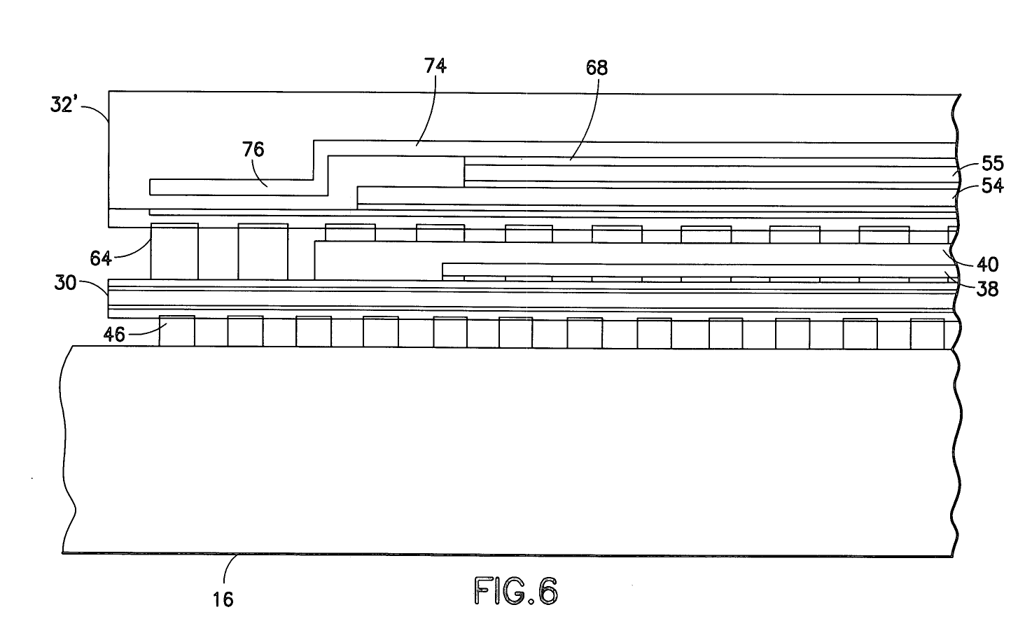

Referring now to FIG. 6, an alternative design of a heat spreader is shown. In this embodiment the second section 32′ is identical to the second section 32 except for the shape of the heat spreader 74. The heat spreader 74 has at least one outer end section 76 which extends downward and outward towards the fusible elements 64. The heat spreader has at least one edge section extending towards the second substrate past a top surface of the second semiconductor die 55. This locates the end section 76 closer to the fusible elements 64 for faster heat transfer to the fusible elements. However, in alternate embodiments, any suitable shape could be provided. In this embodiment, the heat spreader 74 is formed so that it more efficiently conducts the heat to be transported by the substrate/solder balls.

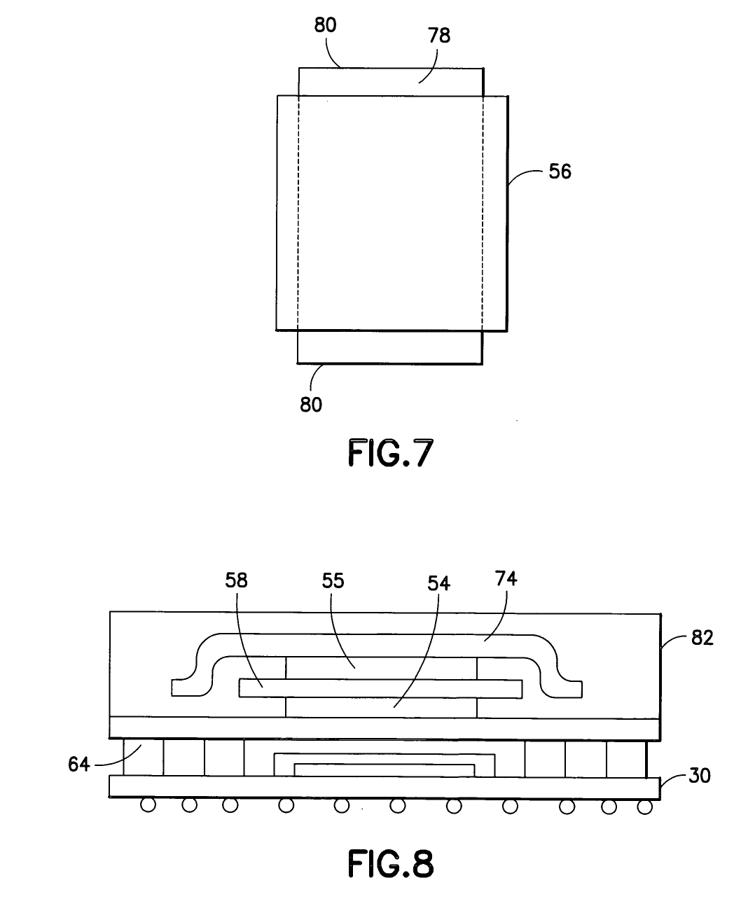

Referring also to FIG. 7 another alternate embodiment is shown. In this embodiment the heat spreader 78 has a general flat rectangular shape with ends 80 that extend out of the second encapsulant material 56. Referring also to FIG. 8 another alternate embodiment is shown. In this embodiment the second package 82 has two heat spreaders 58, 74. The first heat spreader 58 is attached to the bottom die 54 between the two dies 54, 55. The second heat spreader 74 is attached to the top die 55. Thus, both heat spreaders can transfer heat from respective ones of the memory dies 54, 55 through the fusible elements 64 to the first package 30.

With the invention a method of assembling an electronic module assembly can be provided comprising providing a first subassembly comprising a first substrate and a first semiconductor die mounted to a top surface of the first substrate, wherein a bottom side of the first substrate is adapted to be operably mounted on an electronic member; providing a second subassembly comprising a second substrate, at least one second semiconductor die mounted to the second substrate above a top surface of the second substrate, and a heat spreader thermally coupled to the at least one second semiconductor die above a top surface of the second semiconductor die; and connecting the second substrate to the first substrate by conductors extending between a bottom side of the second substrate and the top surface of the first substrate. The heat spreader and conductors are adapted to transfer heat away from the second semiconductor die from the heat spreader to the conductors. The assembly is manufactured before it is connected to the printed circuit board 16. Thus, the assembly can be attached to the PCB 16 in one step as a single unit.

With the invention a method of transferring heat away from a semiconductor memory die in an electronic module assembly can be provided comprising providing a heat spreader on top of the semiconductor die; transferring heat from the semiconductor die to the heat spreader; transferring heat from the heat spreader, through semiconductor die encapsulant material at least partially surrounding the heat spreader, to electrical conductors electrically connected to the semiconductor die; transferring heat from the electrical conductors to a first substrate of a first electronic module subassembly of the electronic module assembly; and transferring heat from the first electronic module subassembly to an electronic member which the first electronic module subassembly is mounted on.

It should be understood that the foregoing description is only illustrative of the invention. Various alternatives and modifications can be devised by those skilled in the art without departing from the invention. Accordingly, the invention is intended to embrace all such alternatives, modifications and variances which fall within the scope of the appended claims.

What is claimed is:

1. An electronic module assembly comprising:
a first substrate;
a first semiconductor die mounted to a top surface of the first substrate;
a second substrate located above the first semiconductor die and electrically and mechanically connected to the top surface of the first substrate;
a second semiconductor die mounted to a top surface of the second substrate;
a heat spreader located above the second semiconductor die and thermally coupled to the second semiconductor die; and
encapsulant material at least partially surrounding the second semiconductor die and the heat spreader.

2. An electronic module assembly as in claim 1 wherein the heat spreader is mounted directly to a top surface of the second semiconductor die by a thermally conductive adhesive.

3. An electronic module assembly as in claim 1 wherein the heat spreader is comprised of at least one material selected of a group comprising aluminum, copper and silicon.

4. An electronic module assembly as in claim 1 wherein the heat spreader is substantially flat.

5. An electronic module assembly as in claim 1 wherein the heat spreader has a general I shape.

6. An electronic module assembly as in claim 1 wherein the heat spreader has a general rectangular shape.

7. An electronic module assembly as in claim 1 wherein the heat spreader extends out of the encapsulant material.

8. An electronic module assembly as in claim 1 wherein the second semiconductor die comprises a plurality of semiconductor dies arranged in a stack.

9. An electronic module assembly as in claim 8 wherein the heat spreader is located at least partially between two of the second semiconductor dies.

10. An electronic module assembly as in claim 1 wherein a bottom side of the second substrate is mechanically and electrically connected to the top surface of the first substrate by fusible elements forming electrical conductors to the second semiconductor die.

11. An electronic module assembly as in claim 1 wherein the heat spreader has at least one edge section extending towards the second substrate past a top surface of the second semiconductor die.

12. An electronic module assembly comprising:
a first section comprising a first substrate and a first semiconductor die electrically and mechanically coupled to the first substrate; and
a second section comprising a second substrate, a second semiconductor die electrically and mechanically coupled to the second substrate, a heat spreader mechanically and thermally coupled to the second semiconductor die and an encapsulant material at least partially surrounding the second semiconductor die and the heat spreader,
wherein the second substrate is electrically coupled to the first substrate by conductors extending directly between the substrates to form the electronic module assembly which is adapted to be mounted to an electronic member has a unitary assembly, and wherein the electronic module assembly is adapted to transfer heat from the second semiconductor die to the heat spreader, through the conductors, and through the first substrate to the electronic number.

13. A portable electronic communications device comprising:
an antenna;
electronic circuitry comprising a transceiver coupled to the antenna, and an electronic module assembly as in claim 12; and
a display coupled to the electronic circuitry.

14. A printed circuit board comprising:
a printed circuit board substrate comprising a heat dissipation layer; and
an electronic module assembly as in claim 12 having conductors of the first substrate connected to a top surface of the printed circuit board substrate by fusible elements.

15. An electronic module assembly as in claim 12 wherein the heat spreader is mounted directly to a top surface of the second semiconductor die by a thermally conductive layer.

16. An electronic module assembly as in claim 12 wherein the heat spreader is comprised of at least one material selected of a group comprising aluminum, copper and silicon.

17. An electronic module assembly as in claim 12 wherein the heat spreader is substantially flat.

18. An electronic module assembly as in claim 12 wherein the heat spreader has at least one edge section extending towards the second substrate past a top surface of the second semiconductor die.

19. An electronic module assembly as in claim 12 wherein the heat spreader extends out of the encapsulant material.

20. An electronic module assembly as in claim 12 wherein the section comprises a plurality of the second semiconductor dies arranged in a stack.

21. An electronic module assembly as in claim 20 wherein the heat spreader is located at least partially between two of the second semiconductor dies.

22. An electronic module assembly as in claim 20 wherein the second section comprises a plurality of the heat spreaders, and wherein each heat spreader is attached to a respective associated one of the second semiconductor dies.

23. An electronic module assembly as in claim 12 wherein the conductors comprise fusible elements.

24. A method of assembling an electronic module assembly comprising:
providing a first subassembly comprising a first substrate and a first semiconductor die mounted to a top surface of the first substrate, wherein a bottom side of the first substrate is adapted to be operably mounted on an electronic member;
providing a second subassembly comprising a second substrate, at least one second semiconductor die mounted to the second substrate above a top surface of the second substrate, and a heat spreader thermally coupled to the at least one second semiconductor die above a top surface of the second semiconductor die; and
connecting the second substrate to the first substrate by conductors extending between a bottom side of the second substrate and the top surface of the first substrate,
wherein the heat spreader and conductors are adapted to transfer heat away from the second semiconductor die from the heat spreader to the conductors.

25. A method of transferring heat away from a semiconductor die in an electronic module assembly comprising:
providing a heat spreader on top of the semiconductor die;
transferring heat from the semiconductor die to the heat spreader;
transferring heat from the heat spreader, through semiconductor die encapsulant material at least partially surrounding the heat spreader, to electrical conductors electrically connected to the semiconductor die;
transferring heat from the electrical conductors to a first substrate of a first electronic module subassembly of the electronic module assembly; and
transferring heat from the first electronic module subassembly to an electronic member which the first electronic module subassembly is mounted on.
